(19) United States
(12) Patent Application Publication
(10) Pub. No.: US 2015/0382469 A1
(43) Pub. Date: Dec. 31, 2015

(54) PACKAGE APPARATUS AND MANUFACTURING METHOD THEREOF

(71) Applicant: PHOENIX PIONEER TECHNOLOGY CO., LTD., Hsinchu County (TW)

(72) Inventors: Chu-Chin HU, Hsinchu County (TW); Shih-Ping HSU, Hsinchu County (TW); E-Tung CHOU, Hsinchu County (TW)

(21) Appl. No.: 14/492,716

(22) Filed: Sep. 22, 2014

(30) Foreign Application Priority Data
Jun. 30, 2014 (TW) 103122515

(51) Int. Cl. H05K 1/18; H05K 3/40; H05K 3/28; H05K 1/14; H05K 3/34

(52) U.S. Cl. CPC H05K 1/185; H05K 1/181; H05K 1/189; H05K 1/141; H05K 3/3452; H05K 3/284; H05K 3/40; H05K 2201/0162; H05K 2201/09563; H05K 2203/1316; H05K 2203/125; H05K 2203/11; H05K 2203/041

(57) ABSTRACT

A package apparatus comprises a first wiring layer, a first conductive pillar layer, a first molding compound layer, a second wiring layer, and a protection layer. The first wiring layer has a first surface and a second surface that are arranged opposite to each other. The first conductive pillar layer is disposed on the second surface of the first wiring layer, whereas the first conductive pillar layer is a non-circular conductive pillar layer. The first molding compound layer is disposed within a specific portion of the first wiring layer and the first conductive pillar layer. The second wiring layer is disposed on the first molding compound layer and one end of the first conductive pillar layer. The protection layer is disposed on the first molding compound layer and the second wiring layer.

### FIELD OF THE INVENTION

The present invention relates to a package apparatus and manufacturing method thereof, and more particularly, to a semiconductor package apparatus and method for manufacturing the same.

### BACKGROUND OF THE INVENTION

With the design trend in electronic devices is toward lighter, smaller, thinner but more functional devices with performance requirements continuing to increase, device manufacturers increasingly need specialty integrated circuit (IC) solutions for allowing billions of miniature electronic components to be densely packed in a small area. Thus, device manufacturers come up with innovative packaging techniques for embedding electronic components in a substrate while allowing shorter traces between the electronic components and the substrate. In addition, the layout area is increased by the use of built-up technique as the technology advances for achieving lighter, smaller, thinner and more functional high-performance devices.

Please refer to FIG. 1, which shows a conventional fiberglass substrate packaging structure. In FIG. 1, the fiberglass substrate packaging structure 10 has a fiberglass substrate 100, which can be made of a bismaleimide triazine (BT), FR-4 or FR-5 fiberglass epoxy resin copper clad laminate. In addition, the fiberglass substrate 100 is formed with a plurality of circular via holes 110 by a laser via method or a mechanical drilling method, by that the plural circular via holes 110 can be provided for receiving a circular conductive pillar layer 120. As shown in FIG. 1, the two first conductive layers 132, 134 are respectively disposed on the fiberglass substrate 100 while allowing the two to connected electrically to the circular conductive pillar layer 120. Moreover, there is further an insulation layer 140 being formed covering on the fiberglass substrate 100, where it is also being processed by either a laser via method or a mechanical drilling method so as to have similarly a plurality of circular via holes 110 formed thereon, by that the two second conductive layers 152, 154 that are respectively disposed on the insulation layer 140 can be connected electrically to the first conductive layers 132, 134 via the circular conductive pillar layer 120.

However, since only the conductive pillar layer 120 with circular via holes can be formed on the aforesaid conventional fiberglass substrates by the application of the mechanism of mechanical drilling or laser via, and as the conductive pillar layer 120 with circular via holes is disadvantageous in its comparatively larger cross-sectional area and thus may not be suitable for high density interconnection substrate, the aforesaid conventional fiberglass substrate can be very costly in manufacture and thus does not have industrial competitive advantages.

### SUMMARY OF THE INVENTION

The present invention provides a package apparatus, by which a molding compound layer can be used as the major material in the manufacturing of a coreless substrate, whereas passive components can be embedded into the coreless substrate in the manufacturing process during the formation of non-circular via holes in a plating non-circular conductive pillar layer and using a molded interconnection system (MIS). Thereby, a multi-layered stack structure of high-density layout can be achieved.

The present invention provides a method for manufacturing a package apparatus, by which the application of costly mechanical drilling or laser via method on conventional fiberglass substrates for forming via holes can be replaced by the use of a less expensive molding compound substrate in cooperation with the method of forming non-circular via holes in a plating non-circular conductive pillar layer. And thereby not only the area for circuit layout in the substrate can be increased, but also the production efficiency can be enhanced.

In an embodiment, the present invention provides a package apparatus, which comprises: a first wiring layer, a first conductive pillar layer, a first molding compound layer, a second wiring layer, and a protection layer. The first wiring layer has a first surface and a second surface that are arranged opposite to each other. The first conductive pillar layer is disposed on the second surface of the first wiring layer, whereas the first conductive pillar layer is a non-circular conductive pillar layer. The first molding compound layer is disposed within a specific portion of the first wiring layer and the first conductive pillar layer. The second wiring layer is disposed on the first molding compound layer and one end of the first conductive pillar layer. The protection layer is disposed on the first molding compound layer and the second wiring layer. The protection layer is a solder resist layer, a photo-sensitive dielectric material layer, or a non-photo-sensitive dielectric material layer.

In another embodiment, the present invention provides a method for manufacturing a package apparatus, which comprises the steps of: providing a metal carrier composed of a first side and a second side that are arranged opposite to each other; forming a first wiring layer on the second side of the metal carrier; forming a first conductive pillar layer on the first wiring layer while allowing the first wiring layer to be formed as a non-circular conductive pillar layer; forming a first molding compound layer on the second side of the metal carrier while allowing the same to cover the first wiring layer and the first conductive pillar layer, and simultaneously enabling the first wiring layer and the first conductive pillar layer to be disposed within the first molding compound layer; enabling one end of the first conductive pillar layer to be exposed; forming a second wiring layer on the first molding compound layer and the exposed end of the first conductive pillar layer; forming a protection layer on the first molding compound layer and the second wiring layer; and removing a portion of the metal carrier so as to form a window while allowing the first wiring layer and the first molding compound layer to be exposed therefrom.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 shows a conventional fiberglass substrate packaging structure.

FIG. 2 is a schematic diagram showing a package apparatus according to a preferred embodiment of the present invention.

FIG. 3 are a top view of a circular conductive pillar layer and a top view of a rectangular conductive pillar layer.

FIG. 4 is a top view of two conventional circular conductive pillar layers.

FIG. 5 is a top view of a rectangular conductive pillar layer according to a first embodiment of the present invention.

FIG. 6 is a top view of a rectangular conductive pillar layer according to a second embodiment of the present invention.

FIG. 7 is a top view of a rectangular conductive pillar layer according to a third embodiment of the present invention.

FIG. 8 is a flow chart depicting steps performing in a method for manufacturing a package apparatus according to a preferred embodiment of the present invention.

FIG. 9A to FIG. 9Q are schematic diagrams illustrating the manufacturing of a package apparatus according to a preferred embodiment of the present invention.

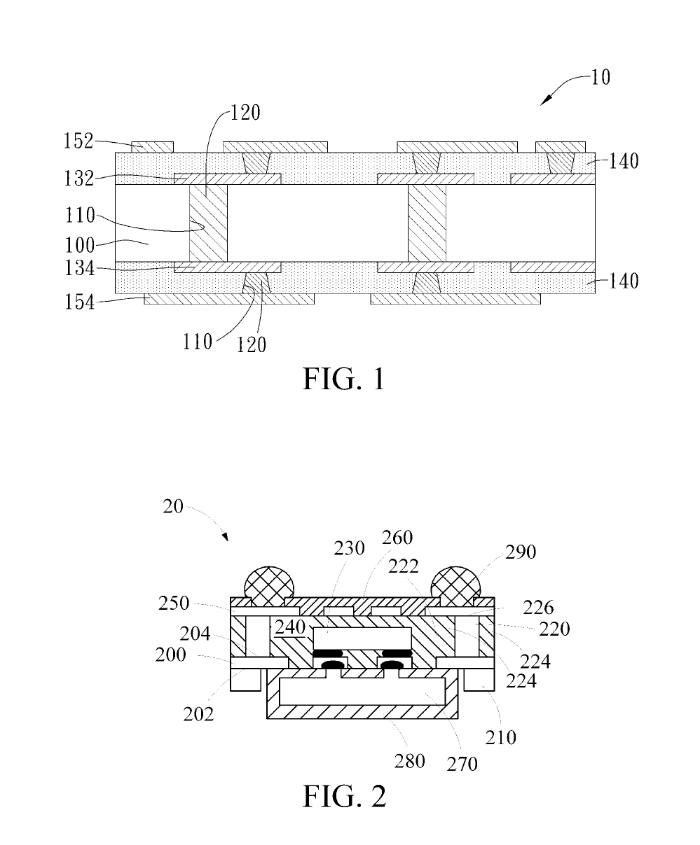

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

Please refer to FIG. 2, which is a schematic diagram showing a package apparatus according to a preferred embodiment of the present invention. As shown in FIG. 2, the package apparatus 20 comprises: a first wiring layer 200, a metal layer 210, a first conductive pillar layer 220, an internal component 230, a first molding compound layer 240, a second wiring layer 250 and a protection layer 260, but is not limited thereby.

The first wiring layer 200 is formed with a first surface 202 and a second surface 204 that are arranged opposite to each other. In this embodiment, the first wiring layer 200 is formed by the use of electrolytic plating means, but is not limited thereby, and can be a wiring layer with patterns which includes at least one wire or a chip seat, and the first wiring layer 200 can be made of a metal, such as copper. In addition, the metal layer 210 is disposed on the first surface 202 of the first wiring layer 200.

The first conductive pillar layer 220 is disposed on the second surface 204 if the first wiring layer 200 while enabling a concave structure 222 to be formed by the formation of the first conductive pillar layer 220 and the first wiring layer 200. It is noted that the first conductive pillar layer 220 in the present invention is formed as a non-circular conductive pillar layer, that can be a layer selected from the group consisting of: a rectangular conductive pillar layer, an octagonal conductive pillar layer, an oval conductive pillar layer, and other non-circular conductive pillar layers of any arbitrary shapes. In addition, the first conductive pillar layer 220 is a wiring layer with patterns which includes at least one wire or a chip seat, but is not limited thereby. In addition, the internal component 230 is disposed on and electrically connected to the second surface 204 of the first wiring layer 200 inside the concave structure 222. In an embodiment, the internal component 230 can be an active component, a passive component, or a semiconductor chip, but is not limited thereby.

The first molding compound layer 240 is disposed on a portion 224 of the first wiring layer 200 and the first conductive pillar layer 220 while allowing the internal component 230 to be disposed inside the first molding compound layer 240. In this embodiment, the first molding compound layer 240 is not exposed on the first surface 202 of the first wiring layer 200 and one end 226 of the first conductive pillar layer 220. It is noted that although the first molding compound layer 240 is formed covering on every portion of the first wiring layer 200 and the first conductive pillar layer 220, but it is not limited thereby. Moreover, the first molding compound layer 240 can be composed of a material selected from the group consisting of novolac-based resin, epoxy-based resin, silicon-based resign and other molding compounds, but it is also not limited thereby. The second wiring layer 250 is disposed on the first molding compound layer 240 and the end 226 of the first conductive pillar layer 220. In addition, the second wiring layer 250 can be a wiring layer with patterns which includes at least one wire or a chip seat, and the protection layer 260 is disposed on the first molding compound layer 240 and the second wiring layer 250.

In an embodiment of the present invention, the package apparatus 20 can further comprises: an external component 270, a second molding compound layer 280 and a plurality of metal balls 290, wherein, the external component 270 is disposed on and electrically connected to the first surface 202 of the first wiring layer 200; the second molding compound layer 280 is disposed on the external component 270 and the first surface 202 of the first wiring layer 200 while allowing the external component 270 to be disposed inside the second molding compound layer 280; and the plural metal balls 290 are disposed on the second wiring layer 250. In addition, the external component 270 is a component selected from the group consisting of: an active component, a passive component, a semiconductor chip and a flexible circuit board.

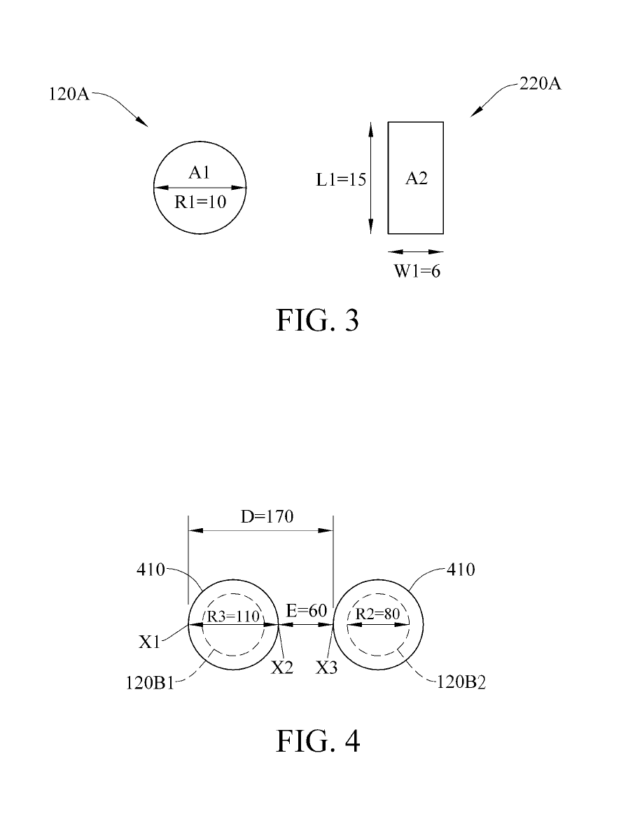

For clarity, in the present invention, the circular conductive pillar layer that is commonly used in conventional package apparatuses is replaced by a non-circular conductive pillar layer of the same resistance (R), and consequently, according to the formula of resistance, i.e.

$$R = ρ \frac{L}{A} ,$$

whereas ρ is the resistivity, L is the resistance length and A is the cross-section area of the resistance, the resistances of a circular conductive pillar layer and a non-circular conductive pillar layer will be the same only if their resistivity ρ, length L and cross-section area A are the same, and thus the non-circular conductive pillar layer that is being used for replacing the conventional circular conductive pillar layer can have the same electrical properties of equal resistance. Please refer to FIG. 3, which are a top view of a circular conductive pillar layer and a top view of a rectangular conductive pillar layer. As shown in FIG. 3, the circular conductive pillar layer 120A is formed with a diameter R1=10 μm, and thus its sectional

$$A 1 = \frac{1}{4} π * {( R 1 )}^{2} = 78.5 {pm}^{2} ;$$

and the rectangular conductive pillar layer 220A is formed with a length L1=15 μm, and a width W1=6 μm, and thus its sectional area A2=L1*W1=80 μm². Notably, the width W1 of the rectangular conductive pillar layer 220A is clearly smaller than the diameter R1 of the circular conductive pillar layer 120A, by that when a rectangular via hole is formed with a sectional area equal to a circular via hole, either the distance between the centers of two neighboring via holes can be effectively reduced, or the amount of wires distributed between via hole to via hole can be increased. Therefore, a design of higher density layout can be achieved, or on the other hand, the production capacity can be increased by allowing the wires to be formed with wider line width while maintaining the same amount of wiring.

Please refer to FIG. 4, which is a top view of two conventional circular conductive pillar layer. As shown in FIG. 4, the two conventional circular conductive pillar layers 120B1, 120B2 with the same sectional areas that are formed with the same diameter R2=80 μm are connected electrically to a circular wiring layer 410, whereas the diameter R3 of the circular wiring layer 410 is 110 μm. In an embodiment, the circular wiring layer 410 is formed with wires or chip seats that are similar to the second wiring layer 250, or even the contact electrodes of the external component 270, but it is not limited thereby. In FIG. 4, the point X1 of a circular wiring layer 410 is spaced from the point X3 of another circular wiring layer 410 by a distance D=170 μm, while the point X2 of a circular wiring layer 410 is spaced from the point X3 of further another circular wiring layer 410 by a distance E=60 μm, and consequently, as the diameters R2 of the two circular conductive pillar layers 120B1, 120B2 are larger than the distance E, it is impossible to have any circular conductive pillar layer to be added between the two neighboring circular wiring layers 410.

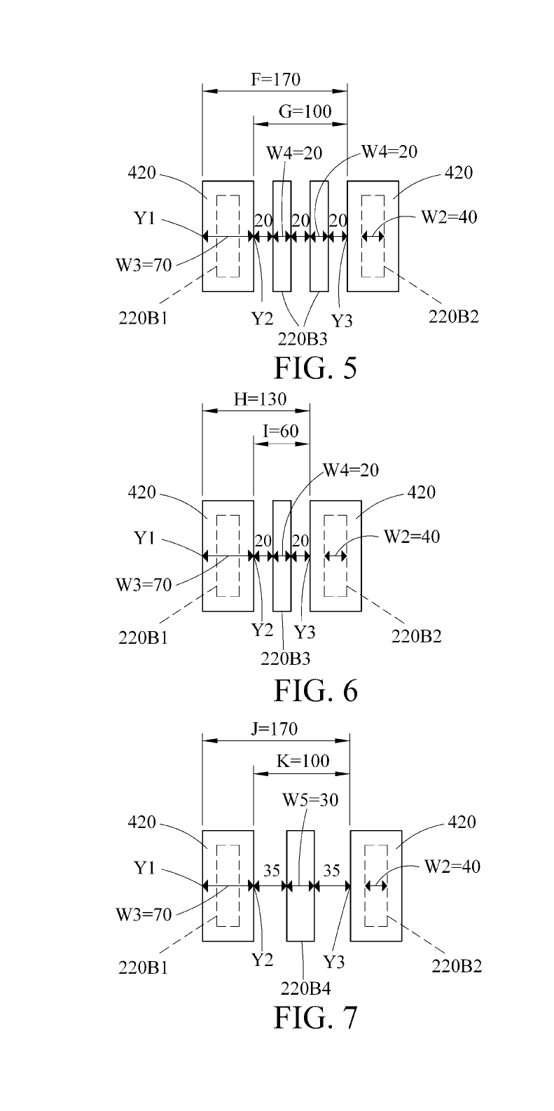

Please refer to FIG. 5, which is a top view of a rectangular conductive pillar layer according to a first embodiment of the present invention. Comparing to embodiment shown in FIG. 4, the two conventional circular conductive pillar layer 120B1, 120B2 are replaced by two rectangular conductive pillar layers 220B1, 220B2 of the same sectional areas, in which both rectangular conductive pillar layers 220B1, 220B2 are formed with the same width W2=40 μm while enabling the two to be connected respectively to rectangular wiring layers 420 which are formed with a width W3=70 μm. Similarly, each of the rectangular wiring layers 420 is formed with wires or chip seats that are similar to the second wiring layer 250, or even the contact electrodes of the external component 270, but it is not limited thereby. In FIG. 5, the point Y1 of a rectangular wiring layer 420 is spaced from the point Y3 of another rectangular wiring layer 420 by a distance F=170 μm, while the point Y2 of a rectangular wiring layer 420 is spaced from the point Y3 of further another rectangular wiring layer 420 by a distance G=100 μm, and consequently, it is sufficient to have two rectangular conductive pillar layers 220B3 of width W4=20 μm to be added between the two neighboring rectangular wiring layers 420, while allowing the two newly added rectangular conductive pillar layers 220B3 to be spaced from each other by a distance of 20 μm and simultaneously enabling the two newly added rectangular conductive pillar layers 220B3 to be spaced from the two rectangular wiring layers 420 by a distance of 20 μm. Thus, it can be realized that the distance of 20 μm is the tolerance for wiring and chip seats allowed in the package apparatus of the present embodiment. Comparing to those shown in FIG. 4, the design shown in the embodiment of FIG. 5 can increase the amount of wiring between via hole to via hole, and thus a design of higher density layout can be achieved.

Please refer to FIG. 6, which is a top view of a rectangular conductive pillar layer according to a second embodiment of the present invention. Comparing to embodiment shown in FIG. 4, the two rectangular conductive pillar layer 220B3 are replaced by one rectangular conductive pillar layer 220B3 that is formed with a width W4=20 μm, while enabling the point Y1 of a rectangular wiring layer 420 to be spaced from the point Y3 of another rectangular wiring layer 420 by a distance H=130 μm, and simultaneously enabling the point Y2 of a rectangular wiring layer 420 is spaced from the point Y3 of another rectangular wiring layer 420 by a distance H=60 μm, enabling the rectangular conductive pillar layers 220B3 to be spaced from the two rectangular wiring layers 420 by a distance of 20 μm. Thus, it can be realized that the distance of 20 μm is the tolerance for wiring and chip seats allowed in the package apparatus of the present embodiment. Comparing to those shown in FIG. 4, the design shown in the embodiment of FIG. 6 can effectively reducing the distance between the centers of two neighboring via holes, and thus a design of higher density layout can be achieved.

Please refer to FIG. 7, which is a top view of a rectangular conductive pillar layer according to a third embodiment of the present invention. Comparing to embodiment shown in FIG. 4, the two rectangular conductive pillar layer 220B3 are replaced by one rectangular conductive pillar layer 220B4 that is formed with a width W5=30 μm, while enabling the point Y1 of a rectangular wiring layer 420 to be spaced from the point Y3 of another rectangular wiring layer 420 by a distance J=170 μm, and simultaneously enabling the point Y2 of a rectangular wiring layer 420 is spaced from the point Y3 of another rectangular wiring layer 420 by a distance K=100 μm, enabling the rectangular conductive pillar layers 220B4 to be spaced from the two rectangular wiring layers 420 by a distance of 35 μm. Thus, it can be realized that the distance of 35 μm is the tolerance for wiring and chip seats allowed in the package apparatus of the present embodiment. Comparing to those shown in FIG. 4, the design shown in the embodiment of FIG. 7 can allow wires in this embodiment to be formed with wider width while maintaining the same amount of wiring, and thus a design of higher density layout can be achieved.

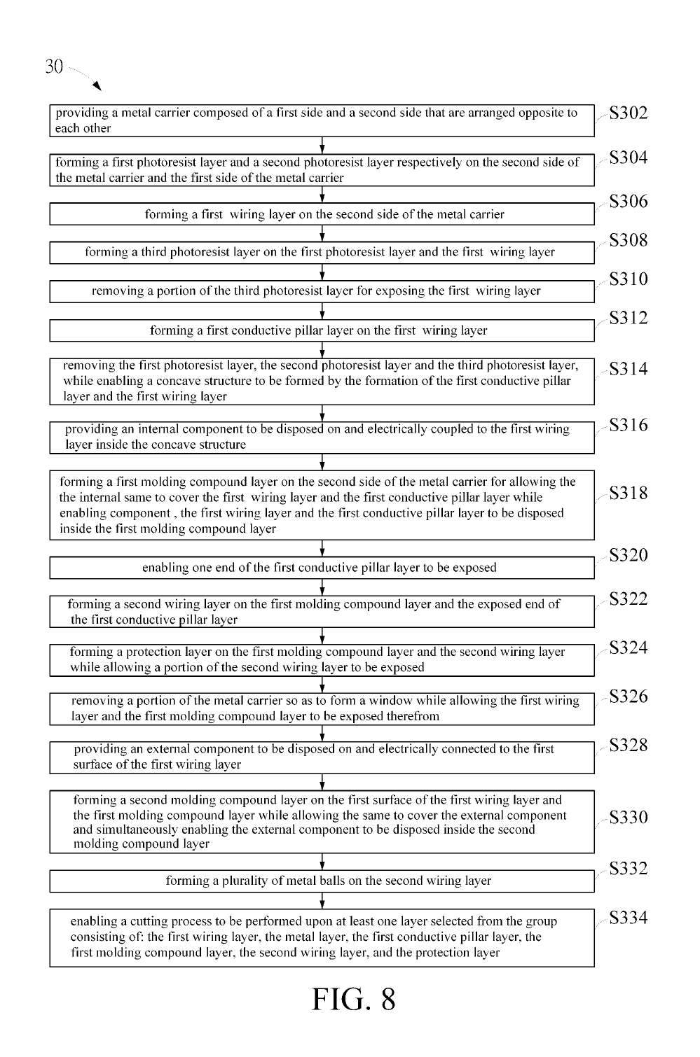

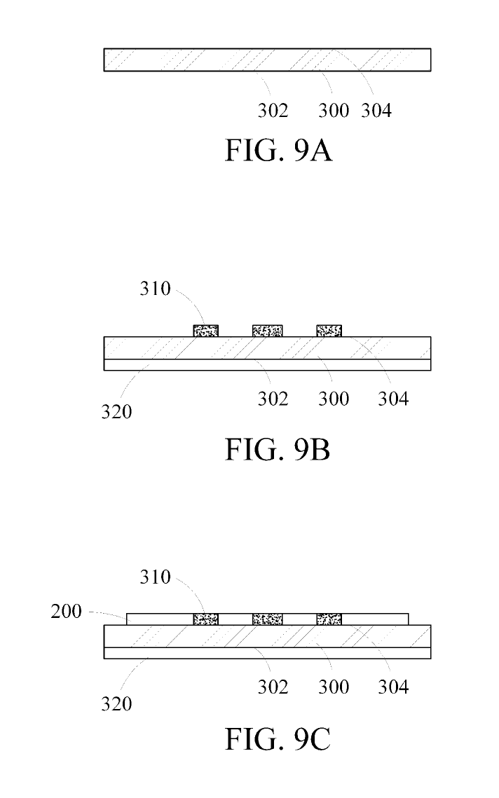

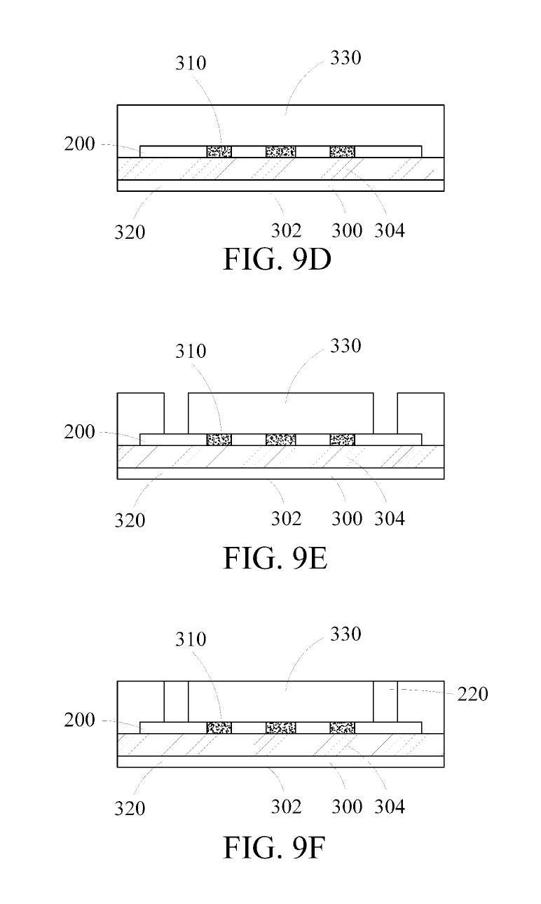

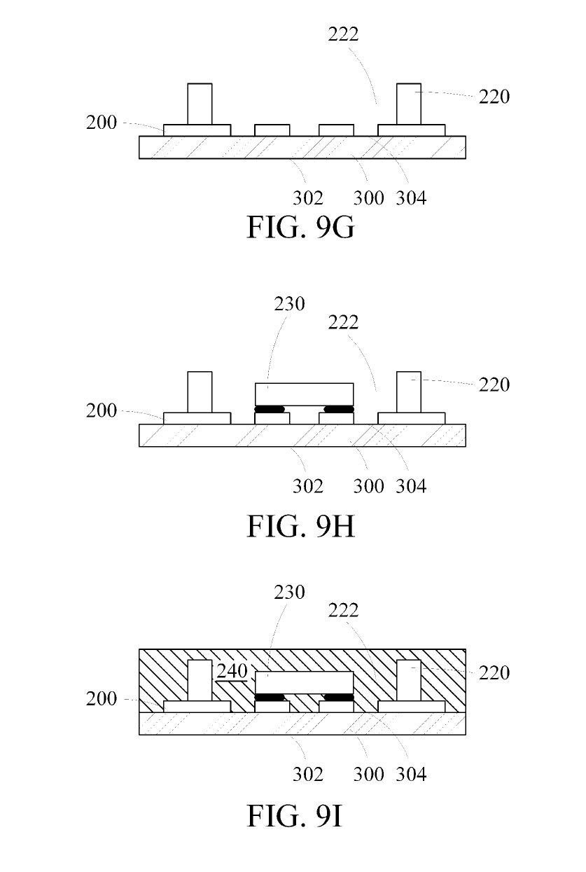

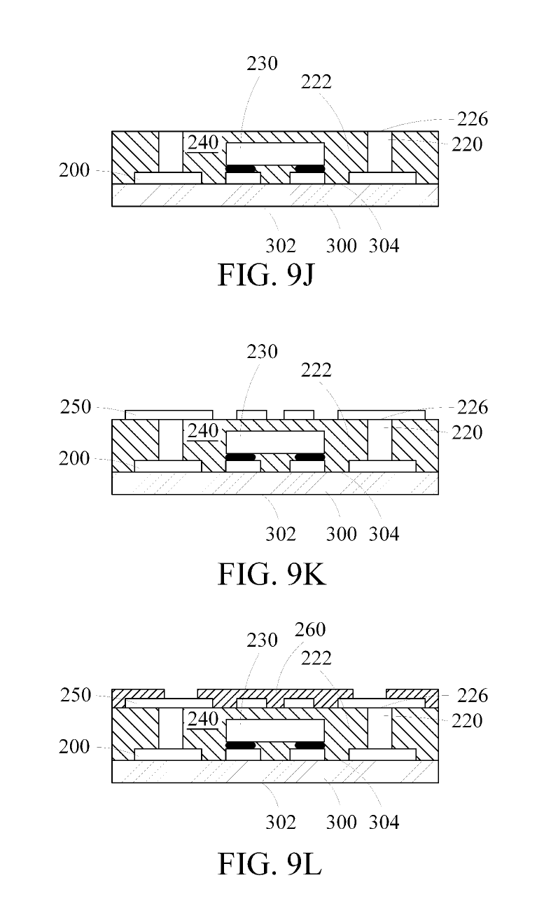

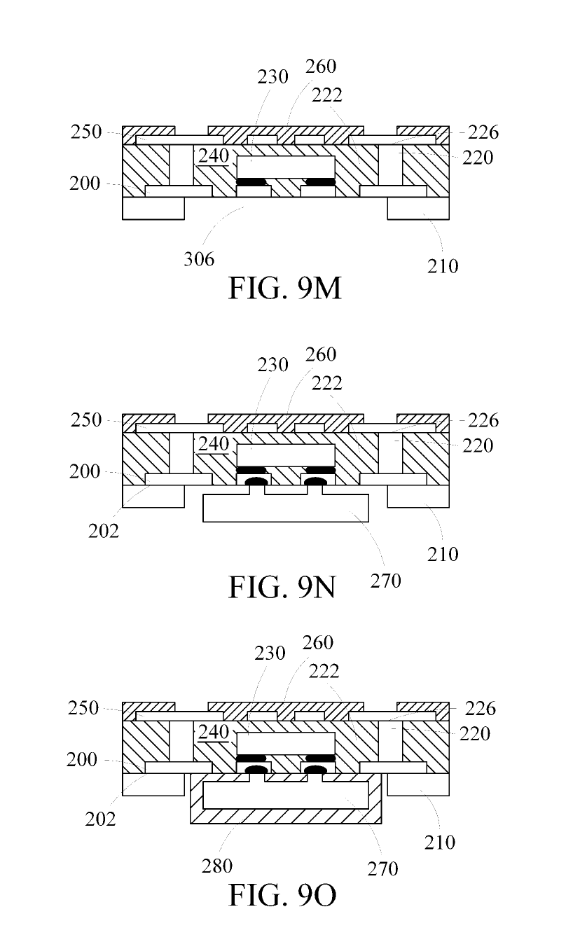

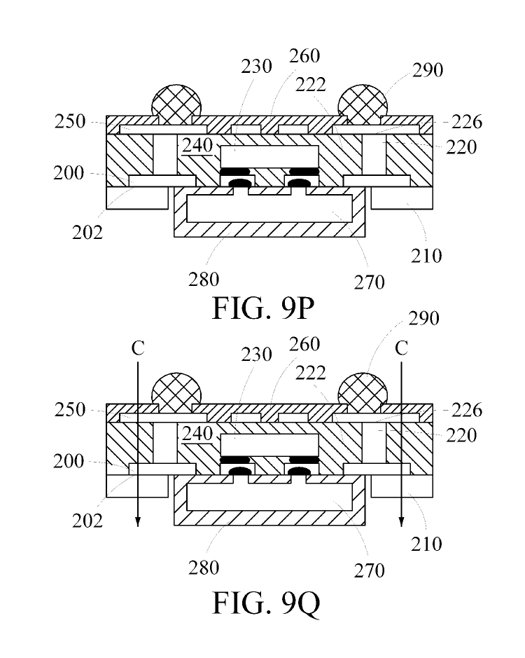

FIG. 8 is a flow chart depicting steps performing in a method for manufacturing a package apparatus of the first embodiment, and FIG. 9A to FIG. 9Q are schematic diagrams illustrating the manufacturing of a package apparatus of the first embodiment. As shown in FIG. 8, a method 30 for manufacturing the package apparatus 20 comprises the following steps:
step S302: providing a metal carrier 300 composed of a first side 302 and a second side 304 that are arranged opposite to each other, as shown in FIG. 9A;
step S304: forming a first photoresist layer 310 and a second photoresist layer 320 respectively on the second side 304 of the metal carrier 300 and the first side 302 of the metal carrier 300, as shown in FIG. 9B, whereas the first photoresist layer 310 is formed using a photolithography process in this embodiment, but is not limited thereby;
step S306: forming a first wiring layer 200 on the second side 304 of the metal carrier 300, as shown in FIG. 9C, whereas the first wiring layer 200 is formed using an electrolytic plating process in this embodiment, but is not limited thereby, and moreover, the first wiring layer 200 can be a wiring layer with patterns which includes at least one wire and a chip seat, and the first wiring layer 200 can be made of a metal, such as copper;
step S308: forming a third photoresist layer 330 on the first photoresist layer 310 and the first wiring layer 200, as shown in FIG. 9D, whereas the third photoresist layer 330 can be formed using a dry-film lamination process in this embodiment, but is not limited thereby;
step S310: removing a portion of the third photoresist layer 330 for exposing the first wiring layer 300, as shown in FIG. 9E, whereas the removal of a portion of the third photoresist layer 330 is performed using a photolithography process, but is not limited thereby;
step S312: forming a first conductive pillar layer 220 on the first wiring layer 200, as shown in FIG. 9F, whereas the first conductive pillar layer 220 is formed as a non-circular conductive pillar layer selected from the group consisting of: a rectangular conductive pillar layer, an octagonal conductive pillar layer, an oval conductive pillar layer, and other non-circular conductive pillar layers of any arbitrary shapes, and is formed using an electrolytic plating process in this embodiment, but is not limited thereby, and moreover, the first conductive pillar layer 220 includes at least one conductive pillar that can be made of a metal, such as copper and is formed at a position corresponding to the wires and the chip seat of the first wiring layer 200;
step S314: removing the first photoresist layer 310, the second photoresist layer 320 and the third photoresist layer 330, while enabling a concave structure 222 to be formed by the formation of the first conductive pillar layer 220 and the first wiring layer 200, as shown in FIG. 9G;
step S316: providing an internal component 230 to be disposed on and electrically connected to the first wiring layer 200 inside the concave structure 222, as shown in FIG. 9H;
step S318: forming a first molding compound layer 240 on the second side 304 of the metal carrier 300 while allowing the same to cover the first wiring layer 200 and the first conductive pillar layer 220 and simultaneously enabling the internal component 230, the first wiring layer 200 and the first conductive pillar layer 220 to be disposed inside the first molding compound layer 240, as shown in FIG. 9I, whereas, in this embodiment, the first molding compound layer 240 is formed by a transfer molding process, and can be made from a material selected from the group consisting of novolac-based resin, epoxy-based resin, silicon-based resign and other molding compounds, whichever can be heated to a liquid state so as to be poured on the second side 304 of the metal carrier 300 for allowing the same to cover the first wiring layer 200, the internal component 230 and the first conductive pillar layer 220 under a high-temperature and high-pressure condition, and thereafter, to be cured into the first molding compound layer 240, and moreover the first molding compound layer 240 can be composed of a kind of filler, such as a powder silicon dioxide; and in another embodiment, the first molding compound layer 240 can be formed by the use of an injection molding process or a compression molding process, and the formation of the first molding compound layer 240 can include the steps of: providing a molding compound to be heated to a liquid state, whereas the molding compound is composed of a resin and powder silicon dioxide; pouring the liquefied molding compound on the second side 304 of the metal carrier 300 while allowing the molding compound to cover the first wiring layer 200, the internal component 230 and the conductive pillar layer 220 under a high-temperature and high-pressure condition; and curing the molding compound for enabling the same to form the first molding compound layer 240, but is not limited thereby;
step S320: enabling one end 226 of the first conductive pillar layer 220 to be exposed, as shown in FIG. 9J, whereas in this embodiment, the exposing of the end 226 of the conductive pillar layer 220 is enabled by grinding and removing a portion of the first molding compound layer 240, however, under ideal condition, the end 226 of the conductive pillar layer 220 is positioned coplanar with the first molding compound layer 240, by that the exposing of the end 226 of the conductive pillar layer 220 can be achieved simultaneously with the formation of the first molding compound layer 240, and thus the process for grinding and removing of the first molding compound layer 240 can be avoided;
step S322: forming a second wiring layer 250 on the first molding compound layer 240 and the exposed end 226 of the first conductive pillar layer 220, as shown in FIG. 9K, whereas the second wiring layer 250 can be formed by the use of an electroless plating process, a sputtering coating process, or a thermal coating process, but is not limited thereby, and moreover, the second wiring layer 250 can be a wiring layer with patterns which includes at least one wire and is a layer formed at a position corresponding to the end 226 of the first conductive pillar layer 220, moreover, the second wiring layer 250 can be made of a metal, such as copper;
step S324: forming a protection layer 260 on the first molding compound layer 240 and the second wiring layer 250 while allowing a portion of the second wiring layer 250 to expose, as shown in FIG. 9L, whereas the protection layer 260 is used for insulating wires in the second wiring layer 250, the protection layer is a solder resist layer, a photo-sensitive dielectric material layer, or a non-photo-sensitive dielectric material layer.;
step S326: removing a portion of the metal carrier 300 so as to form a window 306 while allowing the first wiring layer 200 and the first molding compound layer 240 to be exposed therefrom, as shown in FIG. 9M, whereas the removal of the metal carrier 300 can be performed using a photolithography and etching process, and moreover, the wires and the chip seat of the first wiring layer 200 is also exposed from the window 306, and thus the portion of the metal carrier 300 that is not removed is substantially being formed into a metal layer 210;
step S328: providing an external component 270 to be disposed on and electrically connected to the first surface 202 of the first wiring layer 200, as shown in FIG. 9N, whereas, in an embodiment, the external component 270 can be an active component, a passive component, a semiconductor chip or a flexible circuit board, but is not limited thereby;
step S330: forming a second molding compound layer 280 on the first surface 202 of the first wiring layer 200 and the first molding compound layer 240 while allowing the same to cover the external component 270 and simultaneously enabling the external component 270 to be disposed inside the second molding compound layer 280, as shown in FIG. 9O, whereas, in this embodiment, the second molding compound layer 280 is formed by a transfer molding process, and can be made from a material selected from the group consisting of novolac-based resin, epoxy-based resin, silicon-based resign and other molding compounds, whichever can be heated to a liquid state so as to be poured on the second side 304 of the metal carrier 300 for allowing the same to cover the external component 270, the first surface 202 of the first wiring layer 200 and the first molding compound layer 24, under a high-temperature and high-pressure condition, and thereafter, to be cured into the second molding compound layer 280, and moreover the second molding compound layer 280 can be composed of a kind of filler, such as a powder silicon dioxide; and in another embodiment, the second molding compound layer 280 can be formed by the use of an injection molding process or a compression molding process;
step S332: forming a plurality of metal balls 290 on the second wiring layer 250, as shown in FIG. 9P, whereas each of the metal balls 290 can be made of a metal, such as copper;
step S334: enabling a cutting process C to be performed upon at least one layer selected from the group consisting of: the first wiring layer 200, the metal layer 210, the first conductive pillar layer 220, the first molding compound layer 240, the second wiring layer 250, and the protection layer 260, as shown in FIG. 9Q, by that a package apparatus 20 of FIG. 2 can be achieved.

To sum up, by the use of the package apparatus provided in the present invention where the design of non-circular via holes is used for replacing the conventional circular via holes while maintaining the same cross-section area, either the distance between the centers of two neighboring via holes can be effectively reduced, or the amount of wires distributed between via hole to via hole can be increased. Therefore, a design of higher density layout can be achieved, or on the other hand, the production capacity can be increased by allowing the wires to be formed with wider line width while maintaining the same amount of wiring.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. A package apparatus, comprising:
a first wiring layer, having a first surface and a second surface that are arranged opposite to each other;
a first conductive pillar layer, disposed on the second surface of the first wiring layer, while being formed as a non-circular conductive pillar layer;
a first molding compound layer, disposed within a specific portion of the first wiring layer and the first conductive pillar layer;
a second wiring layer, disposed on the first molding compound layer and one end of the first conductive pillar layer; and
a protection layer, disposed on the first molding compound layer and the second wiring layer.

2. The package apparatus of claim 1, further comprising:
a metal layer, disposed on the first surface of the first wiring layer.

3. The package apparatus of claim 1, wherein the first conductive pillar layer and the first wiring layer are arranged for cooperatively enabling a concave structure to be formed.

4. The package apparatus of claim 3, further comprising:
an internal component, disposed on and electrically connected to the second surface of the first wiring layer in the concave structure while being disposed inside the first molding compound layer.

5. The package apparatus of claim 4, wherein the internal component is a component selected from the group consisting of: an active component, a passive component, and a semiconductor chip.

6. The package apparatus of claim 1, wherein the first molding compound layer is formed not being exposed on the first surface of the first wiring layer and one end of the first conductive pillar layer.

7. The package apparatus of claim 1, further comprising:
an external component, disposed on and electrically connected to the first surface of the first wiring layer;
a second molding compound layer, disposed on the external component and the first surface of the first wiring layer, while allowing the external component to be disposed inside the second molding compound layer; and
a plurality of metal balls, disposed on the second wiring layer.

8. The package apparatus of claim 7, wherein the external component is a component selected from the group consisting of: an active component, a passive component, a semiconductor chip and a flexible circuit board.

9. The package apparatus of claim 1, wherein the first molding compound layer is composed of a material selected from the group consisting of novolac-based resin, epoxy-based resin, silicon-based resign and other molding compounds.

10. The package apparatus of claim 1, wherein the non-circular conductive pillar layer is formed as a layer selected from the group consisting of: a rectangular conductive pillar layer, an octagonal conductive pillar layer, an oval conductive pillar layer, and other non-circular conductive pillar layers of any arbitrary shapes.

11. A method for manufacturing a package apparatus, comprising the steps of:
providing a metal carrier composed of a first side and a second side that are arranged opposite to each other;
forming a first wiring layer on the second side of the metal carrier;
forming a first conductive pillar layer on the first wiring layer while allowing the first wiring layer to be formed as a non-circular conductive pillar layer;
forming a first molding compound layer on the second side of the metal carrier while allowing the same to cover the first wiring layer and the first conductive pillar layer, and simultaneously enabling the first wiring layer and the first conductive pillar layer to be disposed within the first molding compound layer;
enabling one end of the first conductive pillar layer to be exposed;
forming a second wiring layer on the first molding compound layer and the exposed end of the first conductive pillar layer;
forming a protection layer on the first molding compound layer and the second wiring layer; and
removing a portion of the metal carrier so as to form a window while allowing the first wiring layer and the first molding compound layer to be exposed therefrom.

12. The method of claim 11, wherein the first conductive pillar layer and the first wiring layer are arranged for cooperatively enabling a concave structure to be formed.

13. The method of claim 12, further comprising the step of:
providing an internal component to be disposed in a manner that the internal component is disposed on and electrically connected to the first wiring layer in the concave structure while being disposed inside the first molding compound layer.

14. The method of claim 13, wherein the internal component is a component selected from the group consisting of: an active component, a passive component, and a semiconductor chip.

15. The method of claim 11, further comprising the steps of:
providing an external component to be disposed on and electrically connected to the first surface of the first wiring layer;
enabling a second molding compound layer to be formed on the first surface of the first wiring layer and the first molding compound layer for covering the external component while allowing the external component to be disposed inside the second molding compound layer; and
forming a plurality of metal balls on the second wiring layer.

16. The method of claim 11, further comprising the following steps that are to be proceeded before the forming of the first conductive pillar layer on the first wiring layer:
forming a first photoresist layer and a second photoresist layer respectively on the second side of the metal carrier and the first side of the metal carrier;
enabling the first wiring layer to be formed on the second side of the metal carrier;
forming a third photoresist layer on the first photoresist layer and the first wiring layer;
removing a portion of the third photoresist layer for exposing the first wiring layer;
forming a first conductive pillar layer on the first wiring layer; and
removing the first photoresist layer, the second photoresist layer and the third photoresist layer.

17. The method of claim 13, wherein the forming of the first molding compound layer further comprises the steps of:
providing a molding compound, whereas the molding compound is composed of a resin and powder silicon dioxide;
heating the molding compound to a liquid state;
pouring the liquefied molding compound on the second side of the metal carrier while allowing the molding compound to cover the internal component, the first wiring layer, and the first conductive pillar layer under a high-temperature and high-pressure condition; and
curing the molding compound for enabling the same to form the first molding compound layer.

18. The method of claim 15, wherein the external component is a component selected from the group consisting of: an active component, a passive component, a semiconductor chip and a flexible circuit board.

19. The method of claim 11, wherein the first molding compound layer is composed of a material selected from the group consisting of novolac-based resin, epoxy-based resin, silicon-based resign and other molding compounds.

20. The method of claim 11, wherein the non-circular conductive pillar layer is formed as a layer selected from the group consisting of: a rectangular conductive pillar layer, an octagonal conductive pillar layer, an oval conductive pillar layer, and other non-circular conductive pillar layers of any arbitrary shapes.
